(19) United States
(12) Patent Application Publication
(10) Pub. No.: US 2020/0116804 A1
(43) Pub. Date: Apr. 16, 2020

(54) MAGNETIC SENSOR

(71) Applicant: TDK Corporation, Tokyo (JP)

(72) Inventors: Kenichi TAKANO, Tokyo (JP); Yuta SAITO, Tokyo (JP)

(21) Appl. No.: 16/562,521

(22) Filed: Sep. 6, 2019

(30) Foreign Application Priority Data
Oct. 15, 2018 (JP) 2018-194060

(51) Int. Cl. G01R 33/09; H01L 43/02

(52) U.S. Cl. CPC G01R 33/093; H01L 43/10; H01L 43/02

(57) ABSTRACT

A magnetic sensor (1) has a free layer (26) that changes a magnetization direction according to an external magnetic field; a reference layer (24) whose magnetization direction is pinned with respect to the external magnetic field; a spacer layer (25) that is located between the free layer (26) and the reference layer (24) and that has a magneto-resistive effect; a pinned layer (22) that sandwiches the reference layer (24) together with the spacer layer (25) and that is antiferromagnetically coupled to the reference layer (24). A relationship of −2.5≤λP/λR≤0.5 (excluding zero) is satisfied, where λR is a magnetostrictive coefficient of the reference layer (24), and λP is a magnetostrictive coefficient of the pinned layer (22).

### BACKGROUND OF THE INVENTION

### Field of the Invention

The present application is based on, and claims priority from, J.P. Application No. 2018-194060 filed on Oct. 15, 2018, the disclosure of which is hereby incorporated by reference herein in its entirety.

The present invention relates to a magnetic sensor, particularly to a magnetic sensor that uses a magneto-resistive element.

### Description of the Related Art

A magnetic sensor having a magneto-resistive element detects an external magnetic field based on the change of resistance that is caused by the magneto-resistive effect. A magnetic sensor that uses a magneto-resistive element has a higher output and a higher sensibility to a magnetic field than other magnetic sensors and is easier to downsize than other magnetic sensors. The magnetic sensor has a multilayer film structure in which a free layer that changes magnetization direction according to an external magnetic field, a spacer layer that has a magneto-resistive effect, a reference layer and a pinned layer are stacked in this order (JP2011-238342A). The pinned layer and the reference layer are magnetically coupled to each other by the antiferromagnetic coupling, and the magnetization directions are fixed in directions antiparallel to each other. This arrangement stabilizes the magnetization direction of the reference layer. This arrangement also limits the leakage of a magnetic field to the outside because the magnetic field that is released from the reference layer is cancelled by the magnetic field that is released from the pinned layer.

A magnetic sensor is subjected to various stresses during and after fabrication. When the reference layer and pinned layer are subjected to stress, the magnetization directions are changed due to the inverse magnetostriction effect. The change of the magnetization direction may affect the electrical resistance of the magneto-resistive element, as well as the output characteristics of the magnetic sensor. However, the stress to which a magnetic sensor is subjected is often unpredictable, and even if predictable, it is difficult to control. Therefore, in order to ensure the accuracy of a magnetic sensor, it is desired that output of the magnetic sensor not be significantly affected by stress, i.e., the output of the magnetic sensor be insensitive to stress.

The present invention aims at providing a magnetic sensor whose output is less sensitive to stress.

### SUMMARY OF THE INVENTION

A magnetic sensor of the present invention comprises: a free layer that changes a magnetization direction according to an external magnetic field; a reference layer whose magnetization direction is pinned with respect to the external magnetic field; a spacer layer that is located between the free layer and the reference layer and that has a magneto-resistive effect; a pinned layer that sandwiches the reference layer together with the spacer layer and that is antiferromagnetically coupled to the reference layer. A relationship of −2.5≤λP/λR≤0.5 (excluding zero) is satisfied, where λR is a magnetostrictive coefficient of the reference layer, and λP is a magnetostrictive coefficient of the pinned layer.

The present invention can provide a magnetic sensor whose output is less sensitive to stress.

The above and other objects, features and advantages of the present invention will become apparent from the following description with reference to the accompanying drawings which illustrate examples of the present invention.

### BRIEF DESCRIPTION OF THE DRAWINGS

FIG. 1 is a circuit diagram schematically illustrating the configuration of a magnetic sensor;

FIGS. 2A to 2C are conceptual diagrams schematically illustrating the configuration of a magneto-resistive element;

FIGS. 3A and 3B are conceptual diagrams illustrating the output and the offset of a magnetic sensor;

FIG. 4 is a graph showing the relationship between stress and offset change for various values of λP; FIG. 5 is a graph showing the relationship between λP/λR and offset change;

FIGS. 6A to 6C are schematic diagrams illustrating the relationship between the magnetization and stress for the reference layer and the pinned layer; and

FIGS. 7A and 7B are diagrams schematically illustrating a current sensor that uses the magnetic sensor of the present invention.

### DETAILED DESCRIPTION OF THE PREFERRED EMBODIMENT

A magnetic sensor according to an embodiment of the present invention will be described below with reference to the drawings. In the following description and drawings, the X direction refers to the magnetization detecting direction of a magnetic sensor. The X direction coincides with the magnetization directions of the pinned layer and the reference layer and also coincides with the minor axis direction of the magneto-resistive element. The Y direction is orthogonal to the magnetization detecting direction (the X direction) of the magnetic sensor. The Y direction coincides with the magnetization direction of the free layer in a state where no magnetic field is applied and also coincides with the major axis direction of the magneto-resistive element. The Z direction is orthogonal both to the X direction and to the Y direction. The Z direction coincides with the direction in which the layers of the multilayer film of the magneto-resistive element are stacked. It should be noted that the direction of the arrow indicating the X direction in the drawings may be referred to as a +X direction and the direction opposite to the direction of the arrow may be referred to as a −X direction.

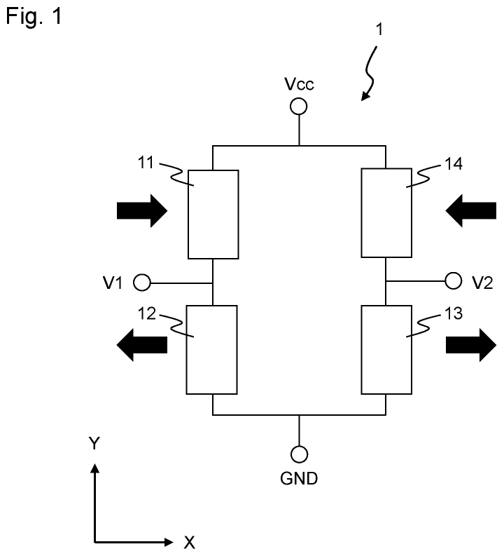

FIG. 1 schematically shows the circuit configuration of the magnetic sensor. Magnetic sensor 1 includes four magneto-resistive elements (hereinafter referred to as first magneto-resistive element 11, second magneto-resistive element 12, third magneto-resistive element 13 and fourth magneto-resistive element 14), and magneto-resistive elements 11 to 14 are interconnected via a bridge circuit (the Wheatstone bridge). Magneto-resistive elements 11 to 14 are divided into two groups, i.e., a group that includes magneto-resistive elements 11, 12 and a group that includes magneto-resistive elements 13, 14. The magneto-resistive elements in each group, i.e., magneto-resistive elements 11, 12 and magneto-resistive elements 13, 14 are connected in series, respectively. The group of magneto-resistive elements 11, 12, as well as the group of magneto-resistive elements 13, 14. is connected to power supply voltage Vcc at one end thereof, and is grounded (GND) at the other end thereof. In addition, midpoint voltage V1 between first magneto-resistive element 11 and second magneto-resistive element 12, as well as midpoint voltage V2 between third magneto-resistive element 13 and fourth magneto-resistive element 14, are outputted. Therefore, midpoint voltages V1, V2 can be determined by the following equations, respectively, where R1 to R4 denote electrical resistances of first to fourth magneto-resistive elements 11 to 14, respectively.

$$\begin{matrix}{V}_{1} = \frac{{R}_{2}}{{R}_{1} + {R}_{2}} {V}_{cc} & ( Equation 1 ) \\ {V}_{2} = \frac{{R}_{3}}{{R}_{3} + {R}_{4}} {V}_{cc} & ( Equation 2 )\end{matrix}$$

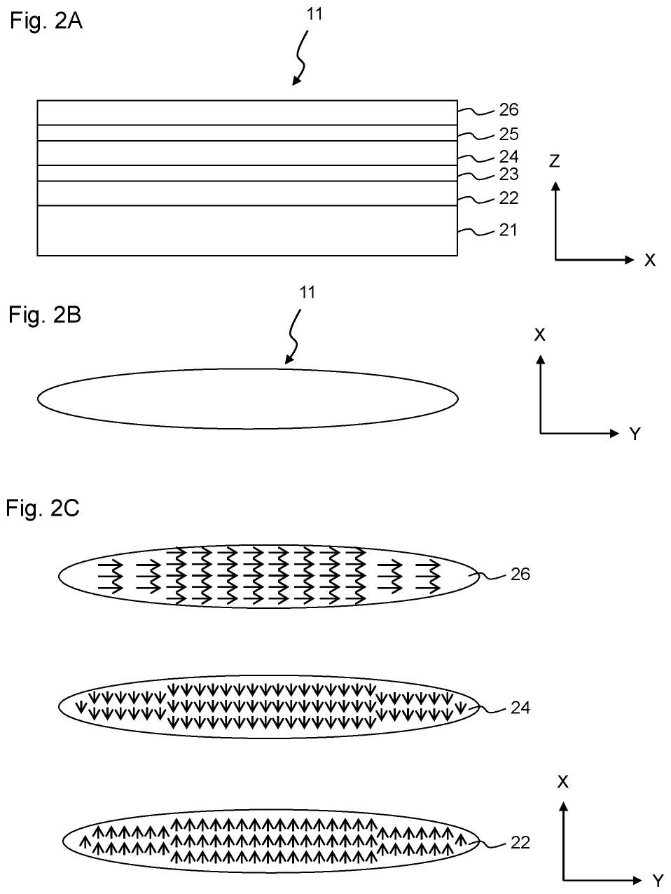

FIGS. 2A to 2C are conceptual diagrams schematically illustrating the configuration of first to fourth magneto-resistive elements 11 to 14. Because first to fourth magneto-resistive elements 11 to 14 have the same configuration, first magneto-resistive element 11 will be described here. FIG. 2A shows the film configuration of first magneto-resistive element 11. First magneto-resistive element 11 has a typical spin valve film configuration. First magneto-resistive element 11 is a stack of films that includes antiferromagnetic layer 21, pinned layer 22, non-magnetic intermediate layer 23, reference layer 24, spacer layer 25 and free layer 26, which are stacked in this order. The stacked films are sandwiched by a pair of electrode layers (not shown) in the Z direction, and a sense current flows in the Z direction from one of the electrode layers to the stacked films.

Free layer 26 is a magnetic layer whose magnetization direction changes according to an external magnetic field. Free layer 26 may be formed, for example, of NiFe. Pinned layer 22 is a ferromagnetic layer whose magnetization direction is pinned with respect to the external magnetic field by the exchange coupling with antiferromagnetic layer 21. Antiferromagnetic layer 21 may be formed of PtMn, IrMn, NiMn and so on. Reference layer 24 is a ferromagnetic layer that is sandwiched between pinned layer 22 and spacer layer 25. Reference layer 24 is magnetically coupled, more specifically, antiferromagnetically coupled, to pinned layer 22 via non-magnetic intermediate layer 23 that is made of Ru, Rh and the like. Therefore, the magnetization directions of reference layer 24 and pinned layer 22 are pinned relative to the external magnetic field, and are antiparallel to each other. Spacer layer 25 is a non-magnetic layer that is located between free layer 26 and reference layer 24 and that has a magneto-resistive effect. Spacer layer 25 is a non-magnetic electrically conductive layer that is made of a non-magnetic metal, such as Cu, or a tunnel barrier layer that is made of a non-magnetic insulator, such as Al₂O₃. When spacer layer 25 is a non-magnetic electrically conductive layer, first magneto-resistive element 11 functions as a giant magneto-resistive (GMR) element, and when spacer layer 25 is a tunnel barrier layer, first magneto-resistive element 11 functions as a tunnel magneto-resistive (TMR) element. Due to a large magnetoresistance ratio and a large output from the bridge circuit, first magneto-resistive element 11 is preferably a TMR element.

As shown in FIG. 2B, first magneto-resistive element 11 has a generally elliptical shape having a major axis and a minor axis, as viewed in the Z direction. FIG. 2C conceptually shows the magnetizations of free layer 26, reference layer 24 and pinned layer 22 in a state where no magnetic field is applied. The arrows in the drawing schematically show the magnetization direction. Free layer 26 is substantially magnetized in the major axis direction (the Y direction) due to the shape anisotropy effect in a state where no magnetic field is applied. In contrast, reference layer 24 and pinned layer 22 are substantially magnetized in the minor axis direction (the X direction), and the magnetization directions are antiparallel to each other, as described above. When an external magnetic field is applied in the X direction, which is the magnetization detecting direction, the magnetization direction of free layer 26 rotates clockwise or counterclockwise in FIG. 2C, depending on the strength of the external magnetic field. The relative angle between the magnetization direction of reference layer 24 and the magnetization direction of free layer 26 changes accordingly, and the electrical resistance to the sense current is changed.

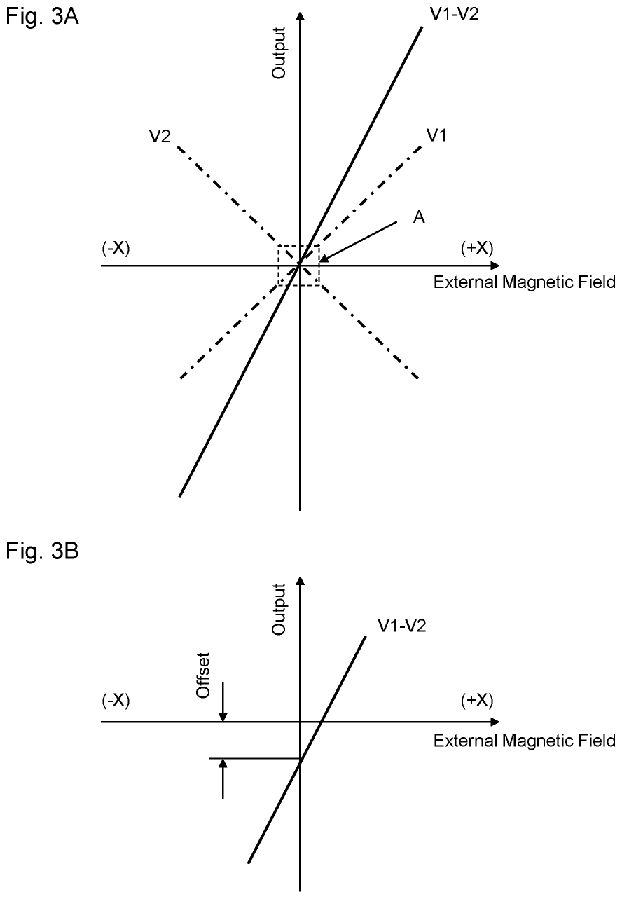

Referring again to FIG. 1, the magnetization of reference layers 24 of first to fourth magneto-resistive elements 11 to 14 are directed in the directions depicted by the arrows in FIG. 1. Therefore, when an external magnetic field is applied in the +X direction, the electrical resistances of first and third magneto-resistive elements 11 and 13 decrease, while the electrical resistances of second and fourth magneto-resistive element 12 and 14 increase. Consequently, midpoint voltage V1 increases while midpoint voltage V2 decreases, as shown in FIG. 3A. Conversely, when an external magnetic field is applied in the −X direction, midpoint voltage V1 decreases while midpoint voltage V2 increases. Detecting difference V1-V2 between midpoint voltages V1 and V2 doubles the sensitivity as compared to detecting midpoint voltages V1 and V2. In addition, even if midpoint voltages V1 and V2 are offset, (i.e., midpoint voltages V1 and V2 are shifted in the direction of the output in FIG. 3A), the influence of the offset can be eliminated by detecting the difference.

However, due to the variations of first to fourth magneto-resistive elements 11 to 14, equations 1 and 2 are not strictly satisfied, and a minor error occurs. Consequently, as shown in FIG. 3B, which is an enlarged view of part A in FIG. 3A, an offset occurs in difference V1-V2. The offset is a deviation of difference V1-V2 from zero in a state where no magnetic field is applied. The offset affects the accuracy of measurement of an external magnetic field. Furthermore, the offset varies depending on the stress acting on first to fourth magneto-resistive elements 11 to 14. The stress acting on first to fourth magneto-resistive elements 11 to 14 is generated by various causes. For example, during fabrication, stress is generated by residual stress in a layer in the wafer process or by grinding or dicing the wafer. When first to fourth magneto-resistive elements 11 to 14 are enclosed in a package, stress is generated by the force that comes from the sealing resin or the like. Stress is also generated when mounting magnetic sensor 1 that is enclosed in a package on a substrate or the like (e.g., a soldering process) in order to produce a module. Stress may also be generated when incorporating a module into a product (e.g., a screw clamping process). Further, during use as a product, thermal stress may be generated, for example, by temperature changes. Some stress is impossible to measure, and the stress is difficult to control even if it can be measured. In essence, it is therefore desired that the offset be less sensitive to stress.

In order to deal with this problem, magnetic sensor 1 of the present embodiment satisfies the relationship of −2.5≤λP/λR≤0.5 (excluding zero) between magnetostrictive coefficient λR of reference layer 24 and magnetostrictive coefficient λP of pinned layer 22. The magnetostrictive coefficient can be determined by forming a thin film of a magnetic material on a substrate and by measuring the displacement of the substrate by means of the optical lever method or the like in a state where the magnetization of the thin film is saturated. It should be noted that the reason why zero is excluded is that, in practice, there cannot be any substance in which λP=0. Description will be given below by some examples.

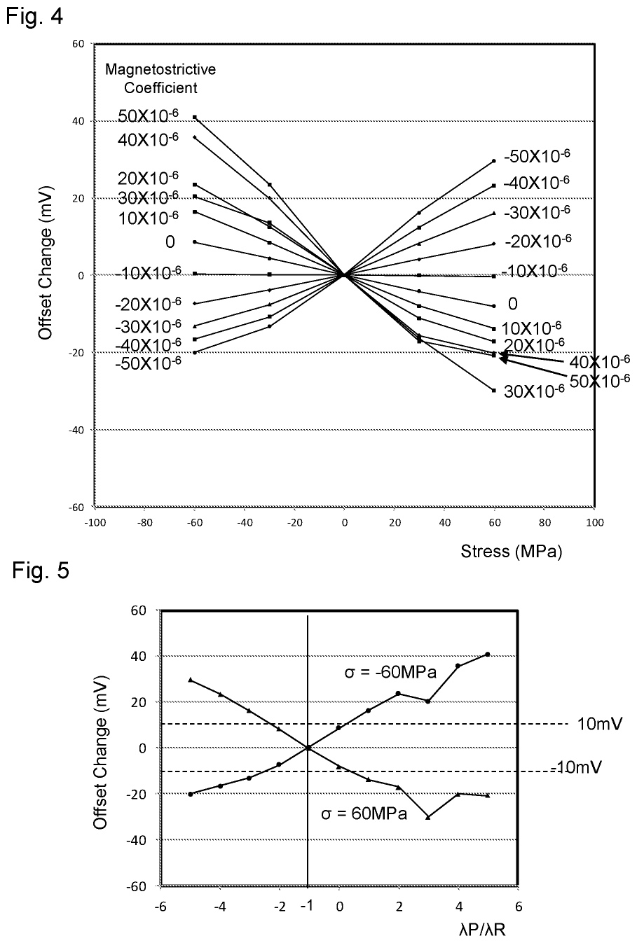

Simulations were conducted using magnetic sensors 1 having the block circuit shown in FIG. 1 and the film configuration shown in FIG. 2A. Magnetostriction constant λR of reference layer 24 was fixed at 10×10⁻⁶, and magnetostrictive coefficient λP of pinned layer 22 was changed within the range of −50×10⁻⁶ to 50×10⁻⁶. First to fourth magneto-resistive elements 11 to 14 each has an elliptical shape that is 3.5 μm long in major axis and 0.5 μm long in minor axis, as viewed in the Z direction. Then, offset changes were measured while tensile stress was applied to first to fourth magneto-resistive elements 11 to 14 in the minor axis direction (the X direction) or in the major axis direction (the Y direction). Free layer 26 has a magnetization film thickness Mst of 80 A (8 emu/cm²) and a magnetostrictive coefficient of −3×10⁻⁶, while reference layer 24 and pinned layer 22 each has a magnetization film thickness Mst of 32 A (3.2 emu/cm²). The result of the evaluation is shown in FIG. 4. The abscissa represents stress. Tensile stress was applied in the minor axis direction (the X direction) in the positive range, while tensile stress was applied in the major axis direction (the Y direction) in the negative range. In other words, compressive stress was applied in the major axis direction (the Y direction) in the positive range, while compressive stress was applied in the minor axis direction (the X direction) in the negative range. The ordinate represents the offset change. The offset change is standardized by the offset value under zero stress. That is, the offset change is a deviation from the offset under zero stress.

It can be seen from FIG. 4 that the offset change increases with the increase of stress. The offset change is not significantly affected by the direction of tensile stress (whether tensile stress is directed in the X direction or in the Y direction) and is approximately symmetrical with respect to the zero-stress point. Because a magnetic sensor that uses a magneto-resistive element generally has a maximum output voltage of around 500 mV, if an offset change that is caused by stress is within around 2%, then the influence of the offset practically does not pose a significant problem. Therefore, it is desirable that the offset change be within about ±10 mV. In addition, it is generally unlikely that a magnetic sensor be subjected to anisotropic stress that is greater than 60 MPa. Thus, the range of λP/λR (ratio of magnetostrictive coefficient λP of pinned layer 22 to magnetostrictive coefficient λR of reference layer 24) was determined in which the offset change is within about ±10 mV under stress of ±60 MPa. As shown in FIG. 5, the offset change is at a minimum when λP/λR=−1, i.e., when magnetostrictive coefficient λR of reference layer 24 and magnetostrictive coefficient ΔP of pinned layer 22 have the same absolute value and opposite signs, and the offset change substantially increases linearly as λP/λR becomes away from −1. In addition, the offset change is not significantly affected by the direction of tensile stress (whether tensile stress is directed in the X direction or in the Y direction). Thus, it is possible to keep the offset change that is caused by stress within a practical range by adjusting λP/λR within a predetermined range around −1.

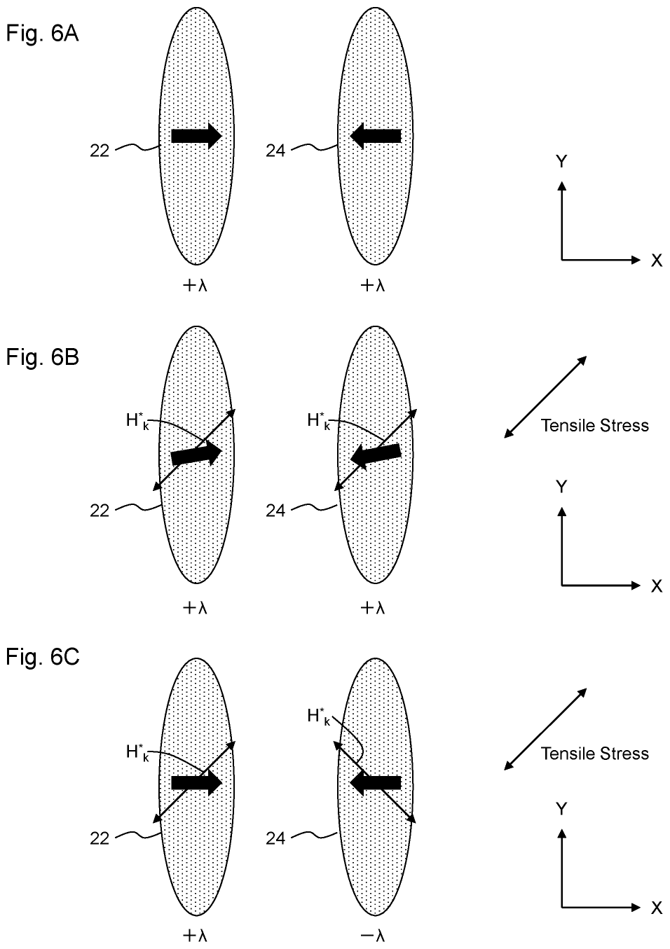

FIGS. 6A to 6C schematically show how the magnetizations of pinned layer 22 and reference layer 24 of a magneto-resistive element are changed when stress is applied. FIG. 6A shows the magnetizations (the thick arrows in the figure) of pinned layer 22 and reference layer 24 of a magneto-resistive element of a comparative example in a state where no stress is applied. The magnetostrictive coefficients of pinned layer 22 and reference layer 24 are positive (see “+λ” in the drawing) and have approximately the same value. As described above, the magnetizations of pinned layer 22 and reference layer 24 are directed in the X direction and are antiparallel to each other. When tensile stress is applied to the magneto-resistive element, as shown in FIG. 6B, an anisotropy energy and an anisotropic magnetic field are induced. Anisotropy energy K*u and anisotropic magnetic field H*k, both induced by stress, are given by the following equations, respectively,

$${K}_{u}^{*} = \frac{3 λ σ}{2}$$

$${H}_{k}^{*} = \frac{3 λ σ}{M}$$

where λ is a magnetostrictive coefficient, σ is stress, and M is the magnetization of each magnetic layer. The magnetization directions of reference layer 24 and pinned layer 22 rotate due to the inverse magnetostriction effect. Because the magnetostrictive coefficients of reference layer 24 and pinned layer 22 are positive, anisotropic magnetic field H*k is induced in the direction parallel to the tensile stress. The magnetization directions of reference layer 24 and pinned layer 22 rotate toward the direction of anisotropic magnetic field H*k. Thus, the magnetization directions of reference layer 24 and pinned layer 22 they rotate in the same direction (in the counterclockwise direction in FIG. 6B). Pinned layer 22, which is antiferromagnetically coupled to reference layer 24, tends to keep reference layer 24 magnetized in a direction antiparallel to the magnetization direction of pinned layer 22. However, since both rotate in the same direction, the effect of pinned layer 22 in preventing the rotation of the magnetization direction of reference layer 24 is limited. In contrast, FIG. 6C shows the magnetizations of pinned layer 22 and reference layer 24 of a magneto-resistive element according to the embodiment. The magnetostrictive coefficient of pinned layer 22 is positive (see “+λ” in the drawing), while the magnetostrictive coefficient of reference layer 24 is negative (see “−λ” in the drawing), and both have the same absolute value. Since the magnetostrictive coefficient of pinned layer 22 is positive, anisotropic magnetic field H*k is induced in a direction parallel to the tensile stress. On the other hand, since the magnetostrictive coefficient of reference layer 24 is negative, anisotropic magnetic field H*k is induced in a direction orthogonal to the tensile stress. However, due to the antiferromagnetic coupling between pinned layer 22 and reference layer 24, the magnetization directions of pinned layer 22 and reference layer 24 do not rotate and continue to be directed in the X direction, unlike FIG. 6B. As a result, the magnetization direction of reference layer 24 is prevented from rotating from the X direction, and the offset change is limited. As can be seen from the foregoing, the offset change can be minimized by setting λP/λR within the range of −1.1 or larger and −0.9 or smaller, more preferably at −1. Even if λP/λR is not within this range, the advantage of the present invention can be achieved as long as λP/λR is in the range of −2.5≤λP/λR≤0.5 (excluding 0).

Magnetostrictive coefficient λR of reference layer 24 and magnetostrictive coefficient λP of pinned layer 22 can be set such that λP/λR is within the above-mentioned range. The signs of magnetostrictive coefficient λR of reference layer 24 and magnetostrictive coefficient λP of pinned layer 22 are not limited. In other words, when λP/λR is positive, both λP and λR may be positive and both may be negative. When λP/λR is negative, λR may be positive while λP negative may be negative, and λR may be negative while λP negative may be positive. That is, at least one layer from among reference layer 24 and pinned layer 22 may be a layer having a positive magnetostrictive coefficient, and at least one layer from among reference layer 24 and pinned layer 22 may be a layer having a negative magnetostrictive coefficient. In addition, there is no limitation on the absolute values of magnetostrictive coefficient λR of reference layer 24 and magnetostrictive coefficient λP of pinned layer 22. The specific configurations of reference layer 24 and pinned layer 22 may be determined by taking other factors into consideration on condition that the above-mentioned condition is satisfied.

When reference layer 24 or pinned layer 22 has a positive magnetostrictive coefficient, reference layer 24 or pinned layer 22 may be made of a CoFe layer or a CoFeX layer, where X is one or more elements selected from the group consisting of B, Ni, Si, Ta, Ti, Hf, V, Zr, W and Mn. Alternatively, reference layer 24 or pinned layer 22 may be made of a stack that includes at least one CoFe layer and at least one CoFeX layer.

When reference layer 24 or pinned layer 22 has a negative magnetostrictive coefficient, reference layer 24 or pinned layer 22 may be made of a Ni layer, a Co layer, a CoNi layer or a NiFe layer. Alternatively, reference layer 24 or pinned layer 22 may be made of a stack that includes two or more from among at least one Ni layer, at least one Co layer, at least one CoNi layer and at least one NiFe layer. In particular, reference layer 24 or pinned layer 22 is preferably made of a stack that includes a Ni layer or a layer that is mainly composed of Ni.

It should be noted that the magnetostrictive coefficient of free layer 26 has not been mentioned in the above description, but the magnetostrictive coefficient of free layer 26 is not largely limited in the present invention. The present inventor has confirmed that λP/λR largely affects the offset change but hardly affects the sensitivity of the magnetic sensor. In other words, the sensitivity of the magnetic sensor is mainly affected by the magnetostrictive coefficient of free layer 26, and the offset change is mainly affected by λP/λR.

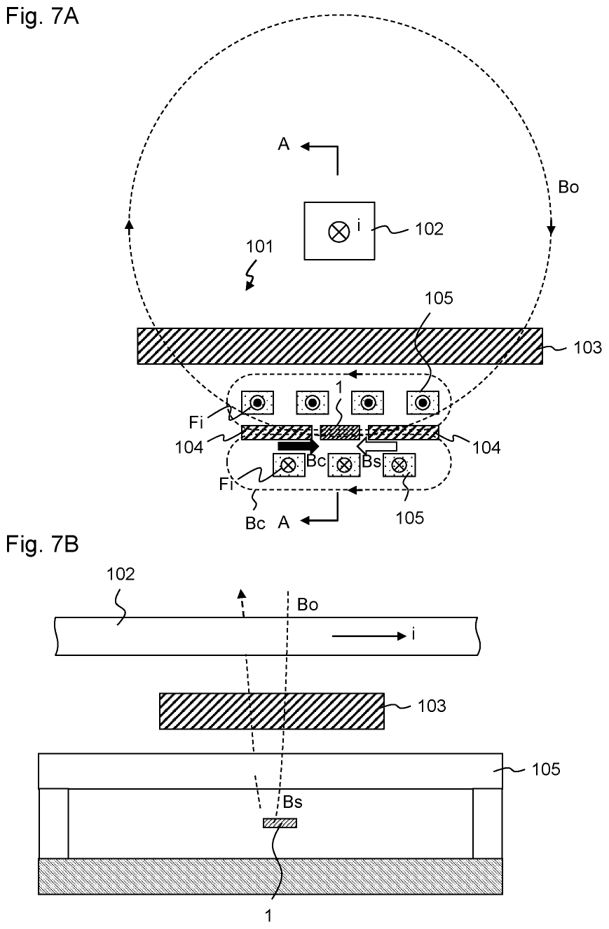

Magnetic sensor 1 described above may be used, for example, for a current sensor. FIG. 7A schematically shows a sectional view of current sensor 101 having magnetic sensor 1. FIG. 7B is a sectional view taken along line A-A in FIG. 7A. Magnetic sensor 1 is installed near electric current line 102 and generates a magnetoresistance change according to a change of signal magnetic field Bs that is applied. Current sensor 101 includes first and second soft magnetic bodies 103, 104, which function as means for adjusting magnetic field strength, and solenoid type feedback coil 105 that is provided near magnetic sensor 1. Feedback coil 105 generates cancelling magnetic field Bc that cancels signal magnetic field Bs. Feedback coil 105 is spirally wound around magnetic sensor 1 and second soft magnetic body 104. Electric current i flows through electric current line 102 in the front-to-back direction (the Y direction) in FIG. 7A and in the left-to-right direction in FIG. 7B. Electric current i induces external magnetic field Bo in a clockwise direction in FIG. 7A. External magnetic field Bo is attenuated by first soft magnetic body 103, is amplified by second soft magnetic body 104, and is then applied leftward to magnetic sensor 1 as signal magnetic field Bs. Magnetic sensor 1 outputs a voltage signal that corresponds to signal magnetic field Bs, and the voltage signal is input to feedback coil 105. Feedback current Fi flows through feedback coil 105 and generates cancelling magnetic field Bc that cancels signal magnetic field Bs. Because signal magnetic field Bs and cancelling magnetic field Bc have the same absolute value and are directed in opposite directions, signal magnetic field Bs is cancelled out by cancelling magnetic field Bc, and the magnetic field that is applied to magnetic sensor 1 becomes substantially zero. Feedback current Fi is converted into a voltage by means of a resistance (not shown) and is outputted as a voltage. Because the voltage is proportional to feedback electric current Fi, cancelling magnetic field Bc and signal magnetic field Bs, the electric current that flows through electric current line 102 can be obtained from the voltage value.

Although certain preferred embodiments of the present invention have been shown and described in detail, it should be understood that various changes and modifications may be made without departing from the spirit or scope of the appended claims.

### LIST OF REFERENCE NUMERALS

1 magnetic sensor

11 first magneto-resistive element

12 second magneto-resistive element

13 third magneto-resistive element

14 fourth magneto-resistive element

21 antiferromagnetic layer

22 pinned layer

23 non-magnetic intermediate layer

24 reference layer

25 spacer layer

26 free layer

λR magnetostrictive coefficient of the reference layer

λP magnetostrictive coefficient of the pinned layer

What is claimed is:

1. A magnetic sensor comprising:
a free layer that changes a magnetization direction according to an external magnetic field;
a reference layer whose magnetization direction is pinned with respect to the external magnetic field;
a spacer layer that is located between the free layer and the reference layer and that has a magneto-resistive effect;
a pinned layer that sandwiches the reference layer together with the spacer layer and that is antiferromagnetically coupled to the reference layer, wherein
a relationship of −2.5≤λP/λR≤0.5 (excluding zero) is satisfied, where λR is a magnetostrictive coefficient of the reference layer, and λP is a magnetostrictive coefficient of the pinned layer.

2. The magnetic sensor according to claim 1, wherein at least one layer from among the reference layer and the pinned layer has a positive magnetostrictive coefficient, and the layer having the positive magnetostrictive coefficient is made of a CoFe layer or a CoFeX layer, where X is one or more elements selected from the group consisting of B, Ni, Si, Ta, Ti, Hf, V, Zr, W, and Mn.

3. The magnetic sensor according to claim 1, wherein at least one layer from among the reference layer and the pinned layer has a positive magnetostrictive coefficient, and the layer having the positive magnetostrictive coefficient forms a stack that includes at least one CoFe layer and at least one CoFeX layer, where X is one or more elements selected from the group consisting of B, Ni, Si, Ta, Ti, Hf, V, Zr, W, and Mn.

4. The magnetic sensor according to claim 1, wherein at least one layer from among the reference layer and the pinned layer has a negative magnetostrictive coefficient, and the layer having the negative magnetostrictive coefficient is made of a Ni layer, a Co layer, a CoNi layer or a NiFe layer.

5. The magnetic sensor according to claim 1, wherein at least one layer from among the reference layer and the pinned layer has a negative magnetostrictive coefficient, and the layer having the negative magnetostrictive coefficient forms a stack that includes two or more from among at least one Ni layer, at least one Co layer, at least one CoNi layer and at least one NiFe layer.

6. The magnetic sensor according to claim 4, wherein the layer having the negative magnetostrictive coefficient includes the Ni layer.

7. The magnetic sensor according to claim 5, wherein the layer having the negative magnetostrictive coefficient includes the Ni layer.

8. The magnetic sensor according to claim 1, wherein a relationship of −0.9≤λP/λR≤−1.1 is satisfied.
